(19) United States
(12) Patent Application Publication
(10) Pub. No.: US 2005/0160345 A1
(43) Pub. Date: Jul. 21, 2005

(54) Apparatus, system, method and computer program product for reliable multicast transport of data packets

(76) Inventors: Rod Walsh, Tampere (FI); Harsh Mehta, Tampere (FI)

Correspondence Address: MORGAN & FINNEGAN, L.L.P., 3 WORLD FINANCIAL CENTER, NEW YORK, NY, 10281-2101, US

(21) Appl. No.: 10/743,948

(22) Filed: Dec. 24, 2003

(51) Int. Cl. H04H 1/00; H04J 3/24; H03M 13/00

(52) U.S. Cl. 714/776

(57) ABSTRACT

An apparatus, system method, and computer program product that combine the attributes of ALC and NORM for communicating data between devices on a network. A sending device uses multiple data rates on different channels to reliably send data packets and receivers use NACKs to request retransmission of missing or mangled data from the sending device or other receiving devices on the network. The sending device using an active ALC mechanism and the receiving devices use NACK and transmitting mechanisms for transmitting acknowledgements or data from the device. The sending and receiving devices can be located in the same or in different networks for communicating data packets during a data transmission session.

### FIELD OF THE INVENTION

The present invention is directed generally to an apparatus, system, method and computer program product for reliable multicast transport of data packets.

### BACKGROUND OF THE INVENTION

For one-to-many services over systems such as IP multicast, file delivery is an important service. Many of the features for delivering files over point-to-point protocols such as file transfer protocol (FTP) and hypertext transfer protocol (HTTP) are problematic for one-to-many scenarios. In particular, the reliable delivery of files using similar one-to-one acknowledgement (ACK) protocols such as transmission control protocol (TCP) is not feasible.

The Working Group of the Internet Engineering Task Force (IETF) (c/o Corporation for National Research Initiatives, Reston, Va., www.ieft.org) is in the process of standardizing two categories of error-resilient multicast transport protocols. In the first category, reliability is implemented through the use of a proactive forward error correction (FEC). In the second category, the protocol uses receiver feedback for reliable multicast transport. Asynchronous Layered Coding (ALC) is a protocol instantiation belonging to the first category, while the NACK-Oriented Reliable Multicast (NORM) protocol is used in the second category. The details of ALC and NORM protocols are discussed in more detail in papers entitled “NACK-oriented Reliable Multicast Protocol” and “Asynchronous Layered Coding (ALC) protocol Instantiation” prepared by the Working Group of the IETF and available at www.ietf.org. The contents of these papers are fully incorporated herein by reference.

Briefly, ALC protocol is a proactive FEC based scheme that allows receivers to reconstruct mangled packets or packets that have not been received. ALC protocol uses FEC encoding on multiple channels, allowing the sender to send data at multiple rates (channels) to possibly heterogeneous receivers. Additionally, ALC protocol uses a congestion control mechanism to maintain different rates on different channels.

ALC protocol is massively scalable in terms of the number of users because no uplink signalling is required. Therefore, any amount of additional receivers does not put increased demand on the system. However, ALC protocol is not 100% reliable because reception is not guaranteed. Accordingly, the repetition of the transmission is necessary. In the best case, the number of retransmissions and any time gap between transmissions is a balance between available bandwidth and the number of users likely to receive 100% of the data. ALC protocol is clearly targeted to multicast delivery over simplex (one-way) links to massive groups with no uplink signalling.

NORM also incorporates the use of FEC on a per-packet basis for repair of damaged packets or packets that have not been received. However, these packets are sent by the sender in response to NACKs received from receivers. The sender employs FEC encoding for the retransmission of packets requested by a receiver. Receivers employ negative acknowledgement (NACK) messages to indicate loss or damage of transmitted packets to the sender. Accordingly, a receiver that “missed” some data blocks from a data transmission can signal the sender using a NACK. NORM protocol also optionally allows for the use of packet-level FEC encoding for proactive robust transmissions.

On a wireless link, however, errors in transmission tend to occur in bursts and thus affect a larger number of blocks and a larger number of receivers at the same time. This could result in a “NACK-implosion,” e.g. a sudden massive number of receivers signalling the sender at the same time by using, for example, either the NACK or the following block retransmission or both. NORM protocol is clearly targeted at multicast delivery over duplex (two-way) links to small and medium sized groups requiring uplink signalling.

The access networks on which these protocols can be used include wireless multiple-access networks such as a universal mobile telecommunications system (UMTS), a wireless local area network (WLAN), a digital video broadcasting-terrestrial (DVB-T) and a digital video broadcasting-satellite (DVB-S).

Both ALC and NORM protocols offer benefits for the multicast transport of data. However, they are targeted at distinct applications: 1) unidirectional (e.g. broadcast DVB-T); and 2) bi-directional (e.g. multicast WLAN) systems. Additionally, a survey of available literature on the topic does not reveal any attempt to combine the above-mentioned features of ALC and NORM protocols.

Accordingly, it would be very useful to enable multicast delivery of data with the massively scalable user groups features of ALC protocol and the 100% rapid reliability of NORM protocol, where an uplink is available to some or all users.

### SUMMARY OF THE INVENTION

To overcome limitations in the prior art described above, and to overcome other limitations that will be apparent upon reading and understanding the present application, an apparatus, system, method and computer program product for reliable multicast transport of data packets are proposed.

The present invention is directed to combining the desirable features of ALC and NORM protocols by allowing a sending device to use multiple data rates on different channels to send data packets and receiving devices to use NACKs to request retransmission of missing or mangling data from the sending device or other receiving devices.

The apparatus and system of the present invention include at least one sending device for transmitting data to at least one receiving device. After receiving the data, the receiving device determines if there is missing or mangled data transmitted from the sending device and sends an acknowledgement or transmission regarding the missing or mangled data to the sending device or to another receiving device.

The apparatus includes at least one processor for determining missing or mangled data in a data transmission, and a NACK and retransmission mechanism. The NACK and retransmission mechanism allows from the transmission of NACKs as well as the transmission of data to the sending device or other receiving devices in the network. The receiving device can be a personal communication device, GPRS, WLAN, DVB of other similar wireless device. The sending device can be a server, IP-based device, GPRS, DVB, or other similar device.

Data is transmitted from said sending device to one or more receiving devices using an active ALC mechanism. By way of example, it is contemplated that the sending device defines unidirectional transmission block identifiers and corresponding objects before transmitting data to the receiving device. The sending device transmits data using a unidirectional protocol. The receiving device then transmits an acknowledgement using a bi-directional or uplink simplex protocol using the same transmission block identifier as the unidirectional protocol.

It is also contemplated by the invention that the system of the present invention includes at least one network for establishing communication between the receiving device and the sending device. The sending device and the receiving device can be located in the same network or in different networks. The networks may include wireless multiple-access networks such as UMTS, WLAN, DVB-T and DVB-S, or a cellular network.

The method of the present invention includes transmitting data packets from at least one sending device via a network to at least one receiving device. The receiving device determines if there is any missing or mangled data. The receiving device then sends an acknowledgement or transmission of missing or mangled data to the sending device or to another receiving device. The sending device or another receiving device retransmits the missing or mangled data to the requesting device to complete the data transmission session.

The acknowledgment or retransmission of missing or mangled data can be multicast or unicast messages. Moreover, a single acknowledgement can contain a plurality of negative acknowledgements messages regarding missing or mangled data, or a positive acknowledgement indicating that the missing or mangled data has been received correctly. Acknowledgements can be transmitted by a sending device or receiving device to the network.

The missing or mangled data can be retransmitted from the sending device or from another receiving device that possesses the missing or mangled data from the original data transmission. It is also contemplated that the retransmission of missing or mangled data can be prioritized based on the acknowledgement received, the number of data transmissions missed, the location of missed or mangled data or the like. For example, retransmitting of the missing or mangled data can be done by retransmitting the original data transmission, retransmitting only the missing data of the original data transmission, or repositioning the missing or mangled data in the data transmission. The retransmission can be sent on different channels and at different data rates.

The computer program product of the present invention includes a computer readable medium for storing computer program code. The program code includes code for transmitting a data packet from at least one sending device to at least one receiving device and determining if there is missing or mangled data transmitted from the sending device. The program code also includes code for sending an acknowledgement or transmission of missing or mangled data to the sending device or to another receiving device as well as program code for retransmission of the missing or mangled data to a receiving device to complete the data transmission session.

### BRIEF DESCRIPTION OF THE DRAWINGS

The accompanying figures show one context for illustrating the details of an apparatus, system, method and computer program product for reliable multicast transport of data packets in accordance with the present invention. However, it is contemplated that other contexts could be used for illustration without departing from the spirit and scope of the invention presented herein. Like reference numbers and designations in these figures refer to like elements.

FIG. 1 is a system diagram of multicast data transport in accordance with an embodiment of the present invention.

FIG. 2 is a detailed diagram of a protocol architecture in accordance with an embodiment of the present invention.

FIG. 3 is a detailed diagram of data flow using ALC in accordance with an embodiment of the present invention.

FIG. 4 is a detailed diagram of data flow using ALC in accordance with an embodiment of the present invention.

FIGS. 5A & 5B illustrate the transmission of data packets in accordance with an embodiment of the present invention.

FIG. 6 is a detailed diagram of data flow using NORM in accordance with an embodiment of the present invention.

FIGS. 7A-7D illustrate data exchange between a sending device and receiving devices in accordance with embodiments of the present invention.

FIGS. 8A-8E illustrate a hierarchical topology for exchanging data between sending devices and receiving devices in accordance with an embodiment of the present invention.

FIGS. 9A-9C illustrate data exchange via a network between a sending device and receiving devices in accordance with an embodiment of the present invention.

FIG. 10 is a detailed diagram of a receiving device in communication with a sending device in accordance with an embodiment of the present invention.

### DETAILED DESCRIPTION OF THE INVENTION

In the following description of the various embodiments, reference is made to the accompanying drawings, which form a part hereof, and in which is shown by way of illustration various embodiments in which the invention may be practiced.

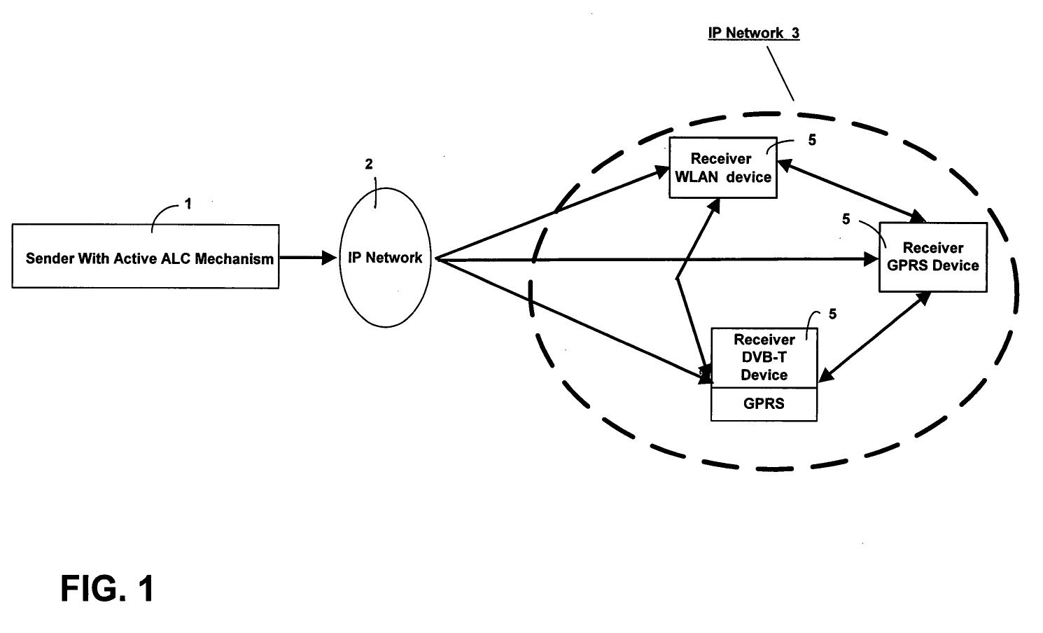

FIG. 1 is a system architecture for multicast data transport in accordance with an embodiment of the present invention. In FIG. 1, the system includes a sending device or sender 1, two IP networks 2, 3 and receiving devices or receivers 5 located within one of the networks 3. The sending device 1 is an server, IP-based device, DVB device, GPRS device or similar device that uses an ALC mechanism for sending multicast data packets.

The ALC mechanism requires LCT, FEC, layered congestion control and security building blocks (not shown). Information in ALC is carried in a session that is characterized by a set of groups/port numbers. Data is transferred as objects. For instance, a file, a JPEG image, a file slice are all objects. A single session may include the transmission of a single object or multiple objects. By way of example, each session is uniquely identified by the IP address of the sender and the transmission session identifier (TSI). Further, the transmission object identifier (TOI) is used to indicate the object to which the packet being transmitted in a particular session pertains. For instance, a sender 1 might send a number of files in the same session using a TOI of 0 for the first file, 1 for the second and so on. On the other hand, the TOI may be a unique global identifier that is being transmitted from several senders 1 concurrently.

The FEC building block provides reliable object delivery within an ALC session. Each object sent in the session is independently encoded using FEC codes. Each source block is represented by a set of encoding symbols. Each packet in an ALC session contains the FEC payload ID that uniquely identifies the encoding symbols that constitute the payload of each packet, and the receiver 5 uses it to determine how the encoding symbols carried in the payload of the packet were generated from the object. When no FEC encoding is used, the block identifier is the triplet of the TOI, the source block number and the encoding symbol ID. The TOI includes the FEC encoding ID 0, the length in bytes of the encoding symbol carried in the packet payload for each source block and the length of the source block in bytes. It is transmitted “out-of-band.” The source block number and the encoding symbol ID together form the FEC payload ID.

In FIG. 1, the first network 2 represents a network of IP hosts and routers that facilitate the communication of data packets between the sender 1 and the receivers 5 in the other network 3. A receiver 5 can be a personal communication device such as a PDA, WLAN device, GPRS device, DVB-T device or other similar wireless device that has a NACK transmission mechanism (not shown) for transmitting NACKs to the sender 1 or other receivers 5 within the network 3.

As seen in FIG. 1, all the receivers 5 are part of the same network 3, which may be a regular IP network, an ad hoc network or a cellular network that is capable of disseminating IP data packets. It is contemplated by the invention, that the sender 1 could also be located within the same network 3 as the receivers 5. Within the network 3, the receivers 5 can communicate with each other, but not necessarily all the time. It is possible for a receiver 5 to send a NACK message to other receivers 5 as well as to the sender 1. The other receivers 5 may then respond to the NACK with a retransmission of the requested data. This is a particularly useful optimization in, for example, proximity area (ad hoc) networks, link-local broadcast, ASM etc.

When sending a NACK, the receivers 5 can use either a unicast or a multicast message. For example, if the receiver 5 has a unicast link to the sender 1, it sends a unicast NACK. If the receiver 5 does not have a unicast link to the sender 1, it sends a multicast NACK to receivers 5 in the multicast group. On the other hand, if the receiver 5 is part of an ad hoc network, it sends a link-local broadcast to other receivers 5 within the ad hoc network. In this case, the sender 1 can also receive the multicast NACK. Additionally, it is possible that the sender 1 is part of the multicast group to which the receiver 5 sends the NACK.

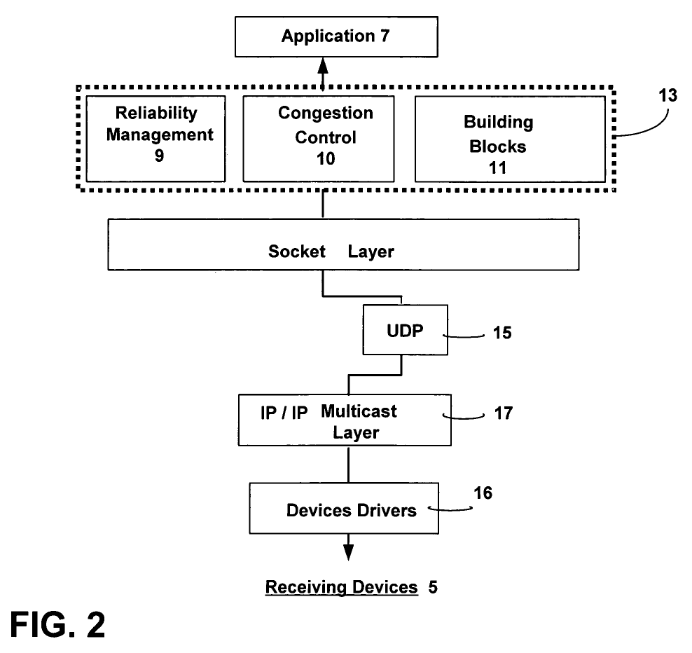

FIG. 2 is a detailed diagram of a protocol architecture in accordance with an embodiment of the present invention. More specifically, FIG. 2 represents a broad view of a reliable multicast infrastructure in the TCP/IP model. In pertinent part, the TCP/IP model includes a high level services layer 13, and a multicast routing layer 17. The high level services layer 13 includes a reliability management feature 9, a congestion control feature 10, and building block feature 11. The reliability management feature 9 controls the reliable transmission of data packet using such protocols as ALC, TRACK, NORM, which work over user datagram protocol (UDP) 15 to provide a ‘TCP-like’ service for multicasting. The congestion control feature 10, and building block feature 11 (e.g. FEC and layered coding transport (LCT)) lie on the same layer as the reliability management feature 9. The multicast layer 17, lies on a separate layer from the high level services layer 13 and facilitates multcast transmission of data packets to receivers 5 via the device drivers 16.

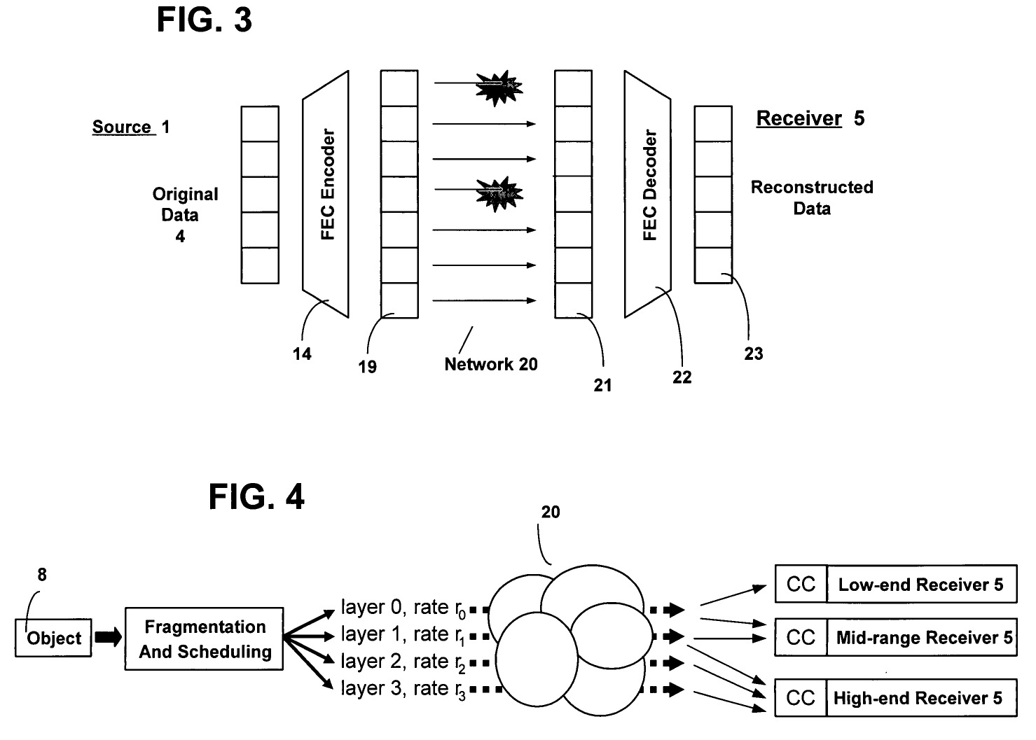

FIGS. 3 & 4 illustrates the unidirectional data flow using ALC. In FIG. 3, the source or sender 1 initiates the transmission of data. The original data 4 is processed by an FEC encoder 14 and fragmented into separate data packets 19. Each data packet 19 is then transmitted via a network 20 to the receivers 5 using separate channels and at different data rates over a network 20. The data transmission from the sender 1 can be received as an incomplete data transmission 21. An FEC decoder 22 then reconstructs the data 23 at the receiver 5 completing the data transmission session.

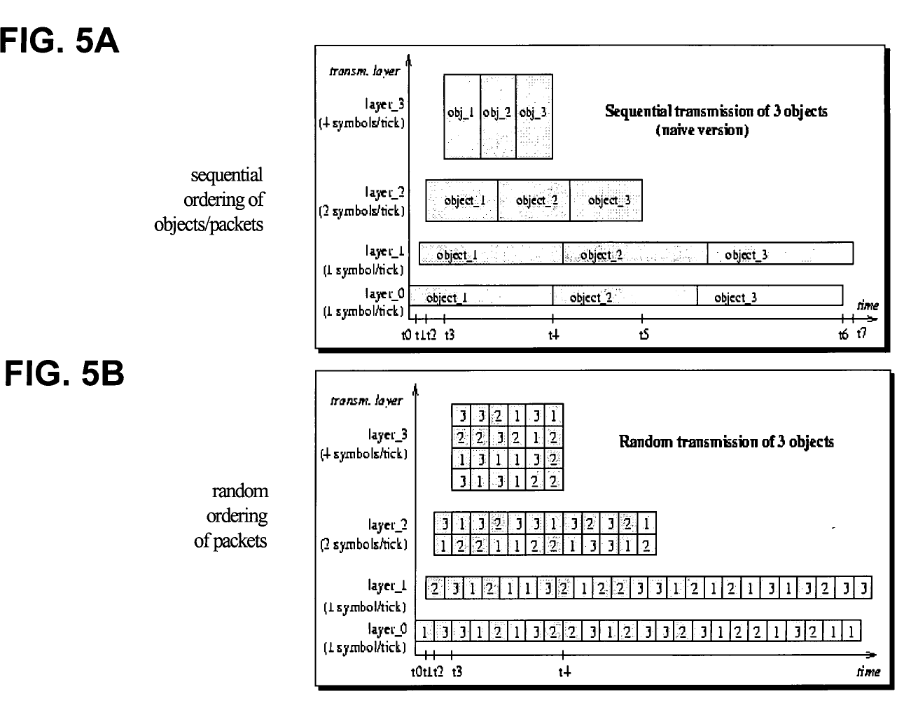

Similarly, in FIG. 4 an object 8 is fragmented into data packets and scheduled for delivery at different rates, as per the congestion control requirements of the high level services layer 13. The data packets are then delivered through multicast transmission via a network 20 to the receivers 5. Objects 8 can be delivered in sequence or in random order. FIGS. 5A & 5B illustrate examples of sequential and random order transmissions for three objects using the ALC mechanism.

The sender operation when using ALC includes all the requirements laid down by the LCT, FEC and multiple rate congestion control feature. A sender using ALC is required to make available the session description as well as the FEC object transmission information “out-of-band” to the receivers. The following is an example:

```
<xs:attribute name=”FEC-OTI-FEC-Instance-ID”
        type=”xs:unsignedLong” use=”optional”/>
<xs:attribute name=”FEC-OTI-Source-Block-Length”
        type=”xs:unsignedLong” use=”optional”/>
<xs:attribute name=”FEC-OTI-Encoding-Symbol-Length”
        type=”xs:unsignedLong” use=”optional”/>
<xs:attribute name=
        ”FEC-OTI-Max-Number-of-Data-Symbols-per-Block”
        type=”xs:unsignedLong” use=”optional”/>
<xs:attribute name=”FEC-OTI-Max-Number-of-Encoding-Symbols”
        type=”xs:unsignedLong” use=”optional”/>
```

FEC object transmission information (OTI) includes one or more of the following: 1) FEC instance identification; 2) source block length; 3) encoding symbol length; 4) maximum number of data symbols per block; and 5) maximum number of encoding symbols.

Within a session a sender transmits a sequence of packets to the channels associated with the session at the appropriate rates as defined by the multiple rate congestion control and building block features. The same TSI is used for all the objects in a session and if more than one object is to be transmitted during the session, then the sender with a unique TOI indicates each object.

A transmission is considered complete if one of several conditions are satisfied: 1) a certain time has expired; 2) a certain number of packets has been sent; or 3) some out-of-band signal, such as a higher level protocol, has indicated completion by a sufficient number of receivers 5. Typically, a receiver 5 joins a certain channel based on information received “out-of-band”. This means that the receiver 5 knows that it should join a particular channel according to its capability based on, for example, SAP messages.

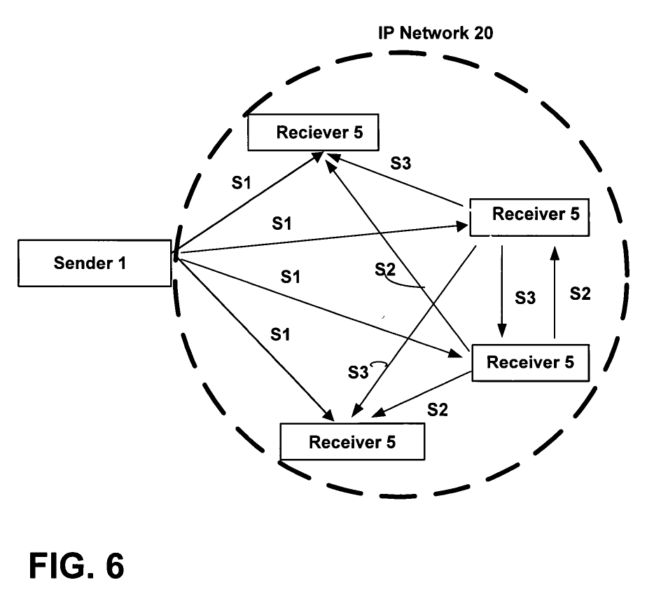

FIG. 6 is a detailed diagram of data flow using NORM in accordance with an embodiment of the present invention. In FIG. 6, the multicast source or sender 1 in step S1 transmits a packet to a number of receivers 5 in an IP network 20. One of the receivers 5 in the network 20 then detects missing or mangled data in the data transmission from the sender 1.

By way of example, missing or mangled blocks can be determined by identifying blocks with some kind of “label,” such as explicit or implicit. Explicit requires defining a new identifier, where as implicit means that the label can be derived from other information (e.g. the TOI, source block identifier and FEC block identifier—as in file delivery over unidirectional transport (FLUTE) protocol.).

Detecting a missing block is easy for linear transmissions as blocks can be labelled and are expected in order. When a block arrives out of order, it may have been lost. It may also be desirable to set an additional timer so that networks known to reorder packets (as with many IP-routed networks) may still deliver packets (and perhaps blocks) very slightly out of order, but lost packets are still detected.

Detecting missed blocks is also readily feasible for other structured transmissions. Examples include “last block first and all blocks in reverse order”, or “every 10^{th} block shifted by one each of ten times.” This is due to the fact that the transmission order is predictable and can be communicated to the receiver 5 in advance, or the receiver 5 can “learn” the order intelligently as the transmission progresses.

The following methods can be used for random or near-random missing block detection (and also the structured cases). A time out based on the expected duration of the whole transmission can be used, or possibly a link-list kind of system (each block identifies the next one or more). It is also possible to signal the end of a transmission explicitly (a null or message block or message explicitly, or finding an already received block implicitly or a combination of these).

Also for the random transmission, it is possible to make it near random by taking the whole transmission and segmenting it so at the end of the segment (instead of the whole transmission) you could do one of the previous “detections.” This is “naturally occurring” for file transfers if a series of files are transmitted one after the other in a single transmission and the FEC blocks are randomised only per file.

The following are other examples of determining missing data blocks also contemplated by the invention:
1. After a certain period (expected duration) of time, it is assumed that the transmission has been received. The blocks still missing are the ones for which the NACK needs to be sent;
2. Each block carries a “pointer” to one or more blocks that should follow it. If these specified blocks are not received after a certain period (or before other blocks), then they are recorded as missing;
3. The end of transmission is signalled with an explicit null message block;
4. The end of transmission is signalled with a message block that has already been sent and received at the receiver; and
5. The end of transmission is signalled by some combination of 3 and 4.

In FIG. 6, after missing or mangled data is determined, the receiver 5 sends a NACK to the other receivers 5 in the network 20 in step S2. For simplification, it is assumed that at least one of the receivers 5 in the network 20 correctly received all the data from the original data transmission. Upon receiving the NACK message, in step S3 the receiver 5 that has correctly received the original data packet from the source 1 transmits the data packet again as a multicast packet. It is also possible that the NACK message is transmitted to the sender 1 as well. In this case, the sender 1 can retransmit the required set of data packets to the receivers 5 in the network 20, e.g. not to all receivers, but to all receivers within a certain scope for example, in the same subnet. Limiting the scope is an important way of avoiding “NACK implosion.”

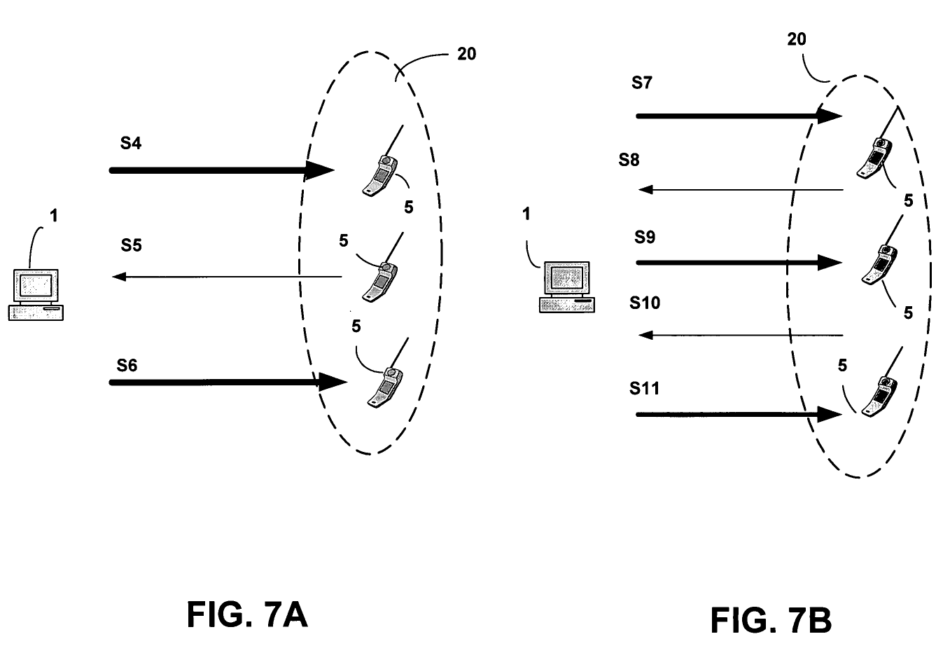

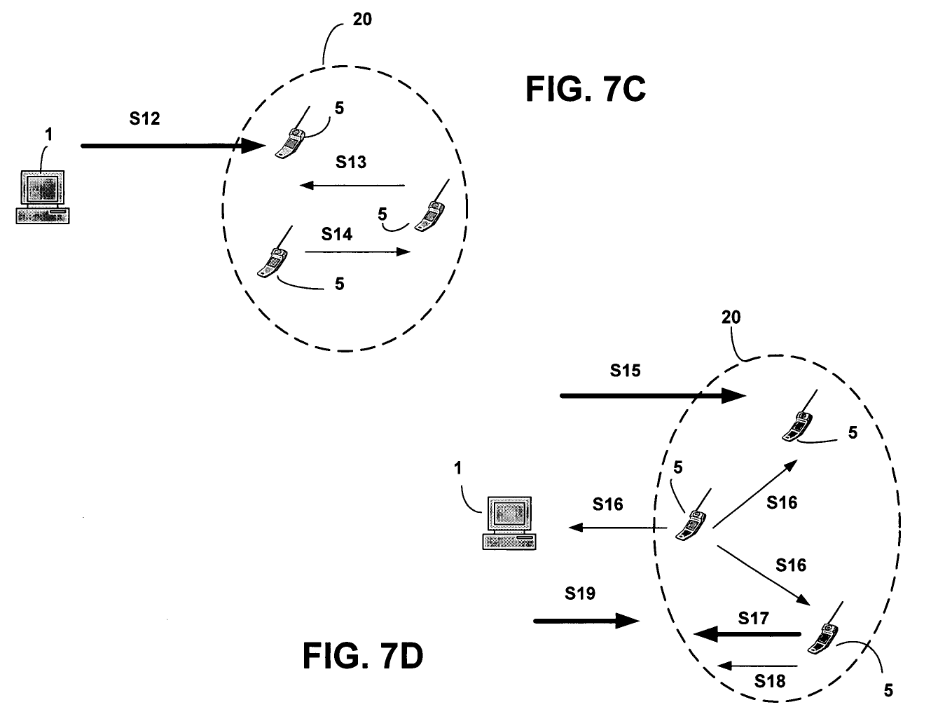

FIGS. 7A-7D illustrate the flow of data exchange between a sending device and receiving devices in accordance with embodiments of the present invention. In FIG. 7A, the sender 1, in step S4, sends a multicast transmission to a group of receivers 5, within a network 20. For the purposes of illustration, the receivers 5 are mobile terminals and the sender 1 is a server. A mobile terminal 5 within the network 20 fails to receive all the data transmitted by the server 1. Accordingly, in step S5 the mobile 5 sends a unicast NACK to the server 1, which retransmits the required packets as multicast packets to the mobile terminals 5 in the network 20 in step S6.

FIG. 7B shows another instance where after a multicast transmission by the server 1 in step S7 and a NACK by one of the mobile terminals 5 in step S8, the server 1 in step S9 multicasts a NACK to all the mobile terminals 5 in the network 20. It is also contemplated by the invention that one or possibly more mobile terminals 5 reply to the NACK by retransmitting the missing blocks to the terminal or terminals making the request. Potentially all of mobile terminals 5 can retransmit data in as a multicast or unicast messages depending on the capabilities of the terminals 5.

With this in mind, in step S10 a mobile terminal 5 responds to the NACK by transmitting data to the server 1 in a unicast message. In step S11, the server 1 then retransmits the missing data back to the other mobile terminals 5 in the network 20. In this case, the server 1 received the missing blocks as a member of the multicast group to which the missing blocks were sent. The NACK from the mobile terminal 5 that did not receive the original transmission was a unicast NACK to the server 1. After receiving the NACK, the server 1 polled the other terminals 5 because it did not have the data itself or for other reasons, such as proximity or aggregation.

Limiting the scope of retransmission can be useful and is also contemplated by the invention. The limitation of retransmission can be based on certain factors, such as proximity. On the other hand, within a multicast group, only one device (i.e., server or terminal) may be designated to retransmit data. Moreover, the retransmissions from the mobile terminals 5 may be limited by the server 1 multicasting an “OK” message after it has received the missing blocks or by the mobile terminal 5 itself by multicasting the missing blocks to all the other mobile terminals 5 in the network 20 or group.

Contrary to the above approaches, in FIG. 7C the NACK and retransmission of data is carried out among the mobile terminals 5 themselves without involving the server 1. This approach may be used in cellular networks and ad hoc networks, as two examples. In step S12, the server 1, transmits an original data transmission to the mobile terminals 5 in the network 20. In step S13, a mobile terminal 5 that did not receive all the data sends a NACK to the other terminals 5 in the network 20. In step S14, a mobile terminal 5 possessing the missing data responds to the NACK by transmitting the data to the terminals 5 in the network 20.

FIG. 7D presents a situation in which a mobile terminal 5 with missing data sends NACKs to the server 1 as well as to the other mobile terminals 5 in the network 20. In step S15, the server 1 transmits a data transmission to the mobile terminals 5 in the network 20. In step S16, A mobile terminal 5 that did not receive all the data from the original transmission sends NACKs to the other mobile terminals 5 in the network 20 and to the server 1. In steps S17 & S18, any mobile terminal that possesses the missing data transmits the data as a unicast or multicast message to the other terminals 5. In step S19, if the retransmission of the data is sent from the server 1, it is transmitted as a multicast data message to the mobile terminals 5 in the network 20. The retransmission may be a multicast transmission from the server, or a unicast or multicast transmission from other mobile terminals 5.

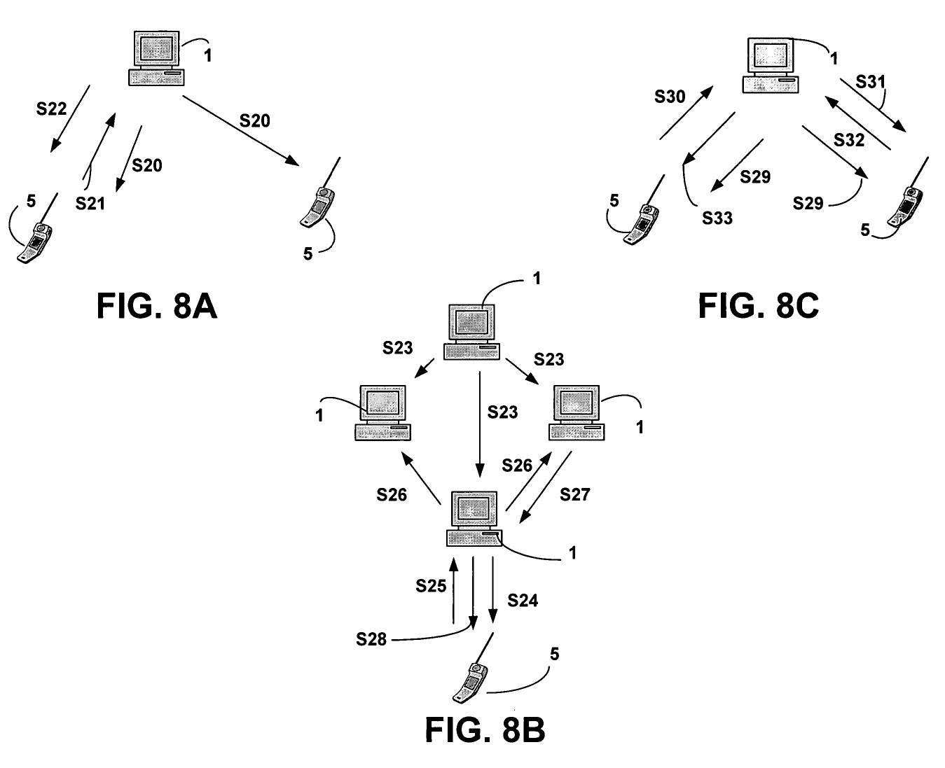

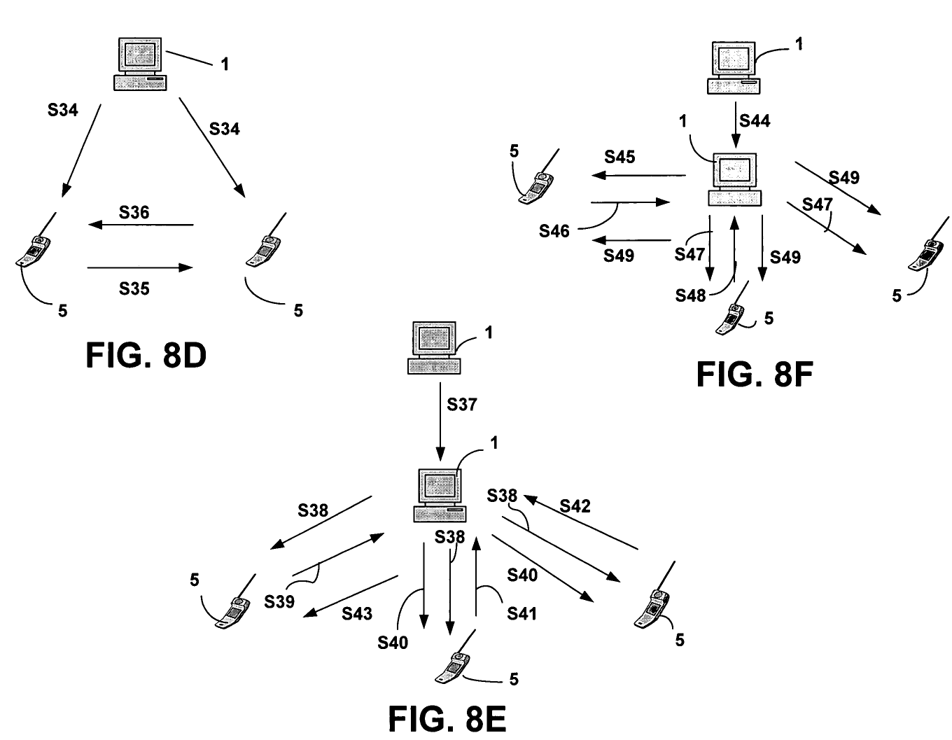

FIGS. 8A-8E illustrate a hierarchical topology for exchanging data between sending devices and receiving devices in accordance with an embodiment of the present invention. By way of example, these figures presents the operation of the proposed scheme in a cellular topology.

FIG. 8A shows the simplest embodiment of a hierarchical topology. Here, in step S21 a NACK mechanism is used by one of the terminals 5 of a server 1 to request retransmission of certain missing blocks from the original multicast data transmitted in step S20 by the server 1. In step S22, the server 1 responds to the NACK by retransmitting the data to the requesting terminal 5.

FIG. 8B shows a server transmitting data to a mobile terminal as a multicast data transmission. Specifically, in step S23, a server 1 transmits an original data transmission to other peer servers 1. The data transmission is then transmitted by one of the servers 1 to a mobile terminal 5 in step S24. However, the mobile terminal 5 does not receive a data packet correctly, and sends a NACK message to the server 1 in step S25. In step S26, the server 1 multicasts this NACK to its peers, that is, other servers 1. In step S27, one of the servers 1 sends the missing packets to the requesting server 1 having forwarded the NACK. In step S28, the server 1 receiving the multicast retransmission, sends it to the mobile terminal 5.

FIG. 8C shows the retransmission mechanism occurring locally, that is, within the domain of the server 1. In FIG. 8C, the server 1 in step S31 retransmits the NACK sent in step S30 to other mobile terminals 5 in its domain that may have received the original multicast transmission accurately in step S29. The terminal 5 possessing the missing data responds to the NACK by retransmitting the data to the server 1 in step S32. In step S33, the server 1 forwards the retransmitted data to the requesting mobile terminal 5. Using a system of timeouts, these methods may be implemented so as to solve the retransmission problem locally before sending out NACK messages.

FIG. 8D shows another instance of usage of the mechanism where the mobile terminal 5 in step S35 sends a NACK to a peer, that is, another mobile terminal 5 based on the original data transmission in step S34. In step S36, the peer mobile terminal 5 responds to the NACK with a retransmission of the original message. The retransmission is accomplished locally without involving the server 1. An ad hoc network with an expanding ring search could also be used to obtain a retransmission, particularly in a situation where the server 1 is not available, but other mobile terminals 5 are proximate.

An expanding ring search works on a proximity basis. First, to the terminals that are within link-local broadcast range (TTL=1). Then if there is no reply, the TTL=2 and the message is forwarded to terminals 5 further away. The TTL value may also be incremented in steps other than value 1. Hence, the number is limited by the number of other terminals 5 present within the given number of hops by the number of hops to the terminal 5. E.g. within 1 hop is within 1 hop proximity, within 2 hops is within 2 hop proximity etc. This is a well-known parameter in ad hoc networks, with several algorithms available to determine this for various radio technologies (e.g. for WLAN).

FIG. 8E presents a case in which the server 1 multicasts the NACK to mobile terminals 5 in its domain and receives several retransmissions of the missing blocks. In step S37, a peer server 1 sends an original data transmission to another server 1. In step S38, the server 1 forwards the data transmission to the mobile devices 5, which result in one of the terminals sending a NACK to the server 1 in step S39. In step S40, the server forwards the NACK to the other terminals 5 in it domain. In steps S41 and S42, the terminals 5 possessing the missing data, respond to the NACK by retransmitting the data to the server 1. In step S43, the server 1 forwards the missing blocks to the requesting terminal 5 in either unicast or multicast fashion.

In FIG. 8F, the scenario is similar. In step S44, the server transmits an original data transmission to another server 1, which forwards it to the mobile terminal 5 in step S45. One of the terminals 5 responds to the original data transmission by sending a NACK to the server 1 in step S46. In step S47, the server 1 forwards the NACK to the other terminals 5 in its domain. However, after receiving the first complete set of missing blocks in step S48 the server 1 in step S49 multicasts a status of“OK” in a message to the mobile terminals 5 in its domain indicating that it has already received the missing blocks and that no more retransmissions are required. This prevents a retransmission implosion at the server 1. Any mobile terminal 5 that did not receive the original transmission will have to resend the NACK after a time out, if it has still not received the required packets. The idea is to minimize the number of retransmissions per NACK.

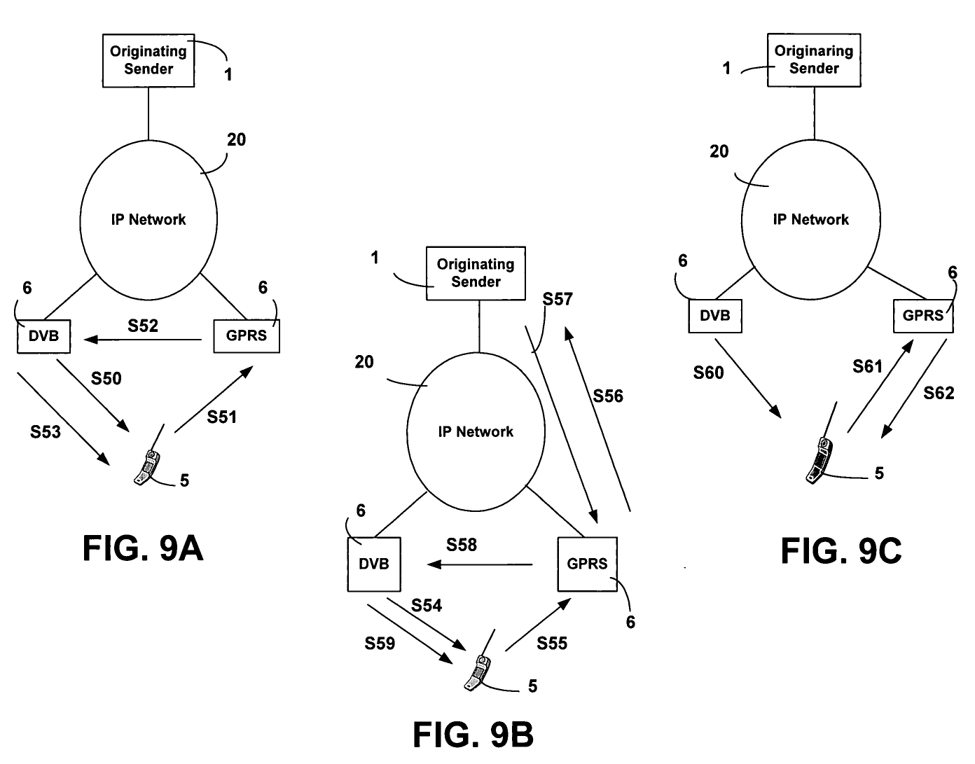

FIGS. 9A-9C presents embodiments of the present invention where multiple network terminal access types are used. The figures present DVB and GPRS devices 6, however, WLAN devices could also replace these for example. All three examples presented in FIGS. 9A-9C show a mobile terminal 5 receiving a multicast data streams via a DVB device 6. A broadcast uplink exists between the DVB device 6 and the terminal 5, while the terminal 5 can communicate in both directions with the GPRS device 6. In effect, the GPRS device 6 can be used for “out-of-band” communication between the terminal 5 and the DVB device 6.

FIG. 9A presents a scenario in which the terminal 5, on detecting missing data in the original data transmission in step S50 sent by a sending device 1 via an IP network 20, sends a NACK to the GPRS device 6 in step S51. The GPRS device 6, in turn, sends the NACK to the DVB device 6 in step S52. In step S53, the DVB device 6 then retransmits either the missing blocks or the entire transmission to the terminal 5.

FIG. 9B is similar except that the DVB device 6 does not have a copy of the missing blocks requested. In step S54, the sending DVB device 6 transmits a data transmission to the terminal 5 received from the originating sender via the IP network 20. In step S55, the terminal 5, sends a NACK to the GPRS device 6. In step S56, the GPRS device 6 sends a NACK message to the originating sender 1 or to any other higher-level router that has a copy of the missing blocks. On receiving the data from the originating sender 1, in step S57, the GPRS device 6 forwards the retransmitted data to the DVB device 6 in step S58, which then retransmits it as a broadcast in step S59.

FIG. 9C shows a case where the GPRS device 6 in step S62 retransmits the missing data blocks to the terminal 5 as a result of the original data transmission in step S60 and NACK in step S61. The missing data blocks can either be cached or obtained from the originating sender by using a NACK mechanism or obtained from the DVB device 6 using a NACK mechanism to the terminal 5 on receiving a NACK. The DVB device 6 is not involved directly in this situation. It is contemplated by the invention that these embodiments may also be used in conjunction with the embodiments presented in FIG. 8A-8F, e.g. when there are multiple terminals present in the network in close proximity.

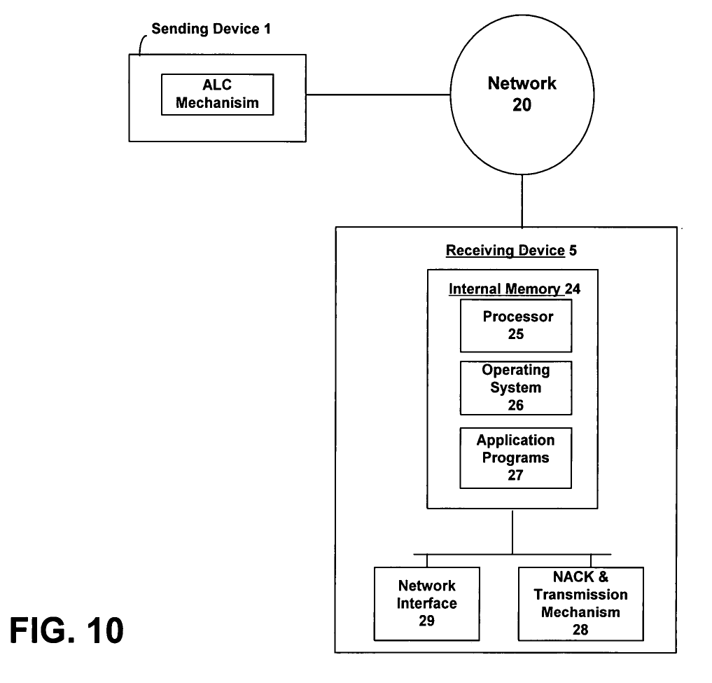

FIG. 10 is a detailed diagram of a receiving device 5 in communication with a sending device in accordance with an embodiment of the present invention. In FIG. 10, the receiving device 5 can be a cellular telephone, a satellite telephone, a personal digital assistant or a Bluetooth device, WLAN device, DVB device, or other similar wireless device. The device 5 includes an internal memory 24, a processor 25, an operating system 26, application programs 27, a NACK & transmission mechanism 28 and a network interface 29. The internal memory 24 accommodates the processor 25, operating system 26 and application programs 27. The NACK & transmission mechanism 28, enables the transmission of NACKs or data to any sending device 1, or receiving devices 5 in response to missing or mangled data blocks in a data transmission. The device 5 is able to communicate with the sending device 1 and other devices via the network interface 29 and IP network 20.

Although illustrative embodiments have been described herein in detail, it should be noted and understood that the descriptions and drawings have been provided for purposes of illustration only and that other variations both in form and detail can be added thereupon without departing from the spirit and scope of the invention. The terms and expressions have been used as terms of description and not terms of limitation. There is no limitation to use the terms or expressions to exclude any equivalents of features shown and described or portions thereof.

1. A method for reliable multicast transport of data packets, comprising:
transmitting a data packet from at least one sending device to at least one receiving device;
determining at said receiving device missing or mangled data transmitted from said sending device;
sending an acknowledgement or transmission of missing or mangled data from said receiving device to said sending device or to another receiving device;
receiving a retransmission of said missing or mangled data from said sending device or said other receiving device to complete the data packet and a data transmission session.

2. The method of claim 1, wherein said acknowledgment of said missing or mangled data is a multicast or unicast negative acknowledgement message.

3. The method of claim 1, wherein said retransmission of missing or mangled data is a multicast or unicast message.

4. The method of claim 1, wherein said missing or mangled data is retransmitted from said sending device or said other receiving device that possesses the missing or mangled data from the data transmission.

5. The method of clam 1, further comprising prioritizing the retransmitting of said missing or mangled data based on said acknowledgement, number of data transmissions missed, location of missed or mangled data or the like.

6. The method of clam 1, further comprising retransmitting said missing or mangled data by retransmitting the original data transmission.

7. The method of claim 1, further comprising retransmitting said missing or mangled data by retransmitting only the missing data of the original data transmission.

8. The method of claim 6, further comprising repositioning said missing or mangled data in the data transmission.

9. The method of claims 1, wherein said retransmission is sent on different channels and at different data rates.

10. The method of claim 1, further comprising sending the original data transmission from said receiving device using an active ALC mechanism.

11. The method of claim 1, further comprising transmitting said acknowledgement or missing or mangled data from said receiving device using a NACK and retransmission mechanism.

12. The method of claim 1, where said missing or mangled data is from a previous transmission, an earlier transmission or a predicted transmission.

13. The method of claim 1, further comprising defining unidirectional transmission block identifiers and corresponding objects before transmitting data to a receiving device.

14. The method of claim 1, wherein said data is transmitted from the sending device using unidirectional protocol.

15. The method of claim 13, wherein said acknowledgement is transmitted by a receiving device using a bi-directional or uplink simplex protocol using the same transmission block identifier as the unidirectional protocol.

16. The method of claim 1, further comprising sending an acknowledgment from said receiving or sending device that the missing or mangled data has been correctly received.

17. The method of claim 1, wherein said acknowledgement contains a plurality of negative acknowledgements regarding missing or mangled data in the data transmission.

18. The method of claim 1, wherein said receiving device is a personal communication device, GPRS, WLAN, DVB of other similar wireless device.

19. The method of claim 1, wherein said sending device is a server, IP-based device, GPRS, DVB other similar wireless device.

20. The method of claim 1, wherein said sending device and said receiving device are in the same network or in different networks.

21. A computer program product for reliable multicast transport of data packets, comprising:
a computer readable medium for storing computer program code;
program code for transmitting a data packet from at least one sending device to at least one receiving device;
program code for determining missing or mangled data transmitted from said sending device;
program code for sending an acknowledgement or transmission of missing or mangled data to said sending device or to another receiving device;
program code for receiving a retransmission of said missing or mangled data from said sending device or said other receiving device to complete transmission of data packet and a data transmission session.

22. The computer program product of claim 21, wherein said acknowledgment of said missing or mangled data is a multicast or unicast negative acknowledgement message.

23. The computer program product of claim 21, wherein said retransmission of missing or mangled data is a multicast or unicast message.

24. The computer program product of claim 21, wherein said missing or mangled data is retransmitted from said sending device or said other receiving device that possesses the missing or mangled blocks.

25. The computer program product of clam 21, further comprising program code for prioritizing the retransmitting of said missing or mangled data based on said acknowledgement received, number of data transmissions missed, location of the missed or mangled data or the like.

26. The computer program product of clam 21, further comprising program code for retransmitting said missing or mangled data by retransmitting the entire original data transmission.

27. The computer program product of 21, further comprising program code for retransmitting said missing or mangled data by retransmitting only the missing data of the original data transmission.

28. The computer program product of claim 25, further comprising program code for repositioning said missing or mangled data in the data retransmission.

29. The computer program product of claims 21, wherein said retransmission is sent on different channels and at different data rates.

30. The computer program product of claim 21, further comprising program code for sending the original data transmission from said sending device using an active ALC mechanism.

31. The computer program product of claim 21, further comprising program code for transmitting said acknowledgement or missing or mangled data from said receiver using a NACK and retransmission mechanism.

32. The computer program product of claim 21, where said missing or mangled data is from a previous transmission, an earlier transmission or a predicted transmission.

33. The computer program product of claim 21, further comprising program code for defining unidirectional transmission block identifiers and corresponding objects before transmitting data to the receiving device.

34. The computer program product of claim 21, wherein said data is transmitted from the sending device using a unidirectional protocol.

35. The computer program product of claim 32, wherein said acknowledgement is transmitted from said receiving device using a bi-directional or uplink simplex protocol using the same transmission block identifier as the unidirectional protocol.

36. The computer program product of claim 21, further comprising program code for sending a positive acknowledgement from said receiving or sending device that the missing or mangled data has been received correctly.

37. The computer program product of claim 21, further comprising program code for sending a plurality of negative acknowledgements in the same negative acknowledgement message.

38. The computer program product of claim 21, wherein said receiving device is GPRS, WLAN, DVB of other similar wireless device.

39. The computer program product of claim 21, wherein said sending device is a server, IP-based device, GPRS, DVB or other similar wireless device.

40. A system for reliable multicast transport of data packets, comprising:
at least one sending device for transmitting data to at least one receiving device;
at least one receiving device for determining missing or mangled data transmitted from said sending device and sending an acknowledgement or transmission of missing or mangled data to said sending device or to another receiving regarding retransmission of at least missing or mangled data;
at least one network for establishing communication between said sending device and said receiving device as well as communication between receiving devices in the network.

41. The system of claim 40, wherein said acknowledgment of said missing or mangled data is a multicast or unicast negative acknowledgement message.

42. The system of claim 40, wherein said retransmission of missing or mangled data is a multicast or unicast message.

43. The system of claim 40, wherein said missing or mangled data are retransmitted from said sending device or another receiving device that possesses the missing or mangled data.

44. The system of clam 40, wherein the retransmission of said missing or mangled data prioritized based on the acknowledgement of missing or mangled data received, number of data transmissions missed, location of missed or mangled data or the like.

45. The system of clam 40, wherein missing or mangled data are retransmitting along with the entire original data transmission.

46. The system of claim 40, wherein retransmitting said missing or mangled data involves retransmitting only the missing data of the original data transmission.

47. The system of claim 40, wherein said retransmitting involves repositioning said missing or mangled data in the data retransmission.

48. The system of claims 40, wherein said retransmission is sent on a different channels and at different data rates.

49. The system of claim 40, wherein said data transmitted from said sending device using an active ALC mechanism.

50. The system of claim 40, further comprising transmitting said acknowledgement from said receiving device using a NACK and retransmission mechanism.

51. The system of claim 40, where said missing or mangled data is from a previous transmission, an earlier transmission or a predicted transmission from said sending device.

52. The system of claim 40, wherein sending device defines unidirectional transmission block identifiers and corresponding objects before transmitting data to the receiving device.

53. The system of claim 40, wherein said sending device transmits data using a unidirectional protocol.

54. The system of claim 52, wherein said receiving device transmit an acknowledgement using a bi-directional or uplink simplex protocol using the same transmission block identifier as the unidirectional protocol.

55. The system of claim 40, wherein said sending device and receiving device are in the same network of different networks.

56. The system of claim 40, wherein said receiving device is personal communication device, GPRS, WLAN, DVB of other similar wireless device.

57. The system of clam 40, wherein said sending device is a server, IP-based device, DVB, GPRS or other similar wireless device.

58. An apparatus for reliable multicast transport of data packets, comprising:
at least one processor for determining missing or mangled data in a data transmisison sent by a sending device.
a NACK and transmission mechanism for sending an acknowledgement or transmission of missing and mangled data to said sending device or to another receiving device; and
a memory for storing the data transmission from the sending device or other receiving device.

59. The apparatus of claim 58,wherein said acknowledgment of said missing or mangled data is a multicast or unicast negative acknowledgement message.

60. The apparatus of claim 58, wherein said retransmission of missing or mangled data is a multicast or unicast message.

61. The apparatus of claim 58, wherein said missing or mangled data is retransmitted from said sending device or other receiving device that possesses the missing or mangled blocks.

62. The apparatus of claim 58, further comprising sending the original data transmission from said server using an active ALC mechanism.

63. The apparatus of claim 58, where said missing or mangled data is from a previous transmission, an earlier transmission or a predicted transmission.

64. The apparatus of claim 58, wherein said receiving device is personal communication device, GPRS, WLAN, DVB of other similar wireless device.
